(19) United States
(12) Patent Application Publication
(10) Pub. No.: US 2026/0360448 A1
(43) Pub. Date: Nov. 12, 2026

(54) Memory Circuitry

(71) Applicant: Cirrus Logic International Semiconductor Ltd., Edinburgh (GB)

(72) Inventors: John P. LESSO, Edinburgh (GB); Scott P. WARRICK, Austin, TX (US)

(73) Assignee: Cirrus Logic International Semiconductor Ltd., Edinburgh (GB)

(21) Appl. No.: 19/351,435

(22) Filed: Oct. 7, 2025

Related U.S. Application Data
(60) Provisional application No. 63/802,940, filed on May 9, 2025.

(51) Int. Cl. G11C 16/32; G11C 16/04; G11C 16/10; G11C 16/28

(52) U.S. Cl. CPC G11C 16/32; G11C 16/0466; G11C 16/102; G11C 16/28

(57) ABSTRACT

Memory circuitry, comprising: an input node for receiving a time-varying input signal; an intermediate node; a circuit element having a reactance, the circuit element coupled between the input node and the intermediate node; a memory element having a programmable resistance, the memory element coupled between the intermediate node and a reference node, and processing circuitry coupled to the intermediate node, the processing circuitry configured to determine a characteristic of the memory element based on a time-varying response signal at the intermediate node.

### TECHNICAL FIELD

The present disclosure relates to memory circuitry comprising programmable resistances, such as charge trap transistors, and memory systems comprising the same.

### BACKGROUND

In conventional non-volatile memory systems, such as NOR flash memory, stored data is read by applying fixed voltages to a bit line or word line of a memory matrix and measuring resultant currents or voltages using sense circuitry or sense amplifiers. These approaches are often limited in precision, scalability, and energy efficiency.

### SUMMARY

According to an aspect of the disclosure, there is provided memory circuitry, comprising: an input node for receiving a time-varying input signal; an intermediate node; a circuit element having a reactance, the circuit element coupled between the input node and the intermediate node; a memory element having a programmable resistance, the memory element coupled between the intermediate node and a reference node, and processing circuitry coupled to the intermediate node, the processing circuitry configured to determine a characteristic of the memory element based on a time-varying response signal at the intermediate node.

The memory element may comprise a charge trap transistor having a programmable threshold voltage.

The memory element may comprise a memristor.

The circuit element may comprise a capacitor or an inductor.

The time-varying input signal may comprise a step function, an impulse function, a chirp, or a sweep.

The memory circuitry may further comprise drive circuitry coupled to the input node, the drive circuitry configured in a read mode to apply the time-varying input signal at the input node.

In the read mode, the drive circuitry may be further configured to apply a gate voltage at a gate of the CTT to bias the CTT in a linear region of operation.

In a programming mode, the drive circuitry may be configured to program the programmable resistance of the memory element.

The drive circuitry may be configured to program the programmable resistance of the memory element by applying a programming voltage at a gate of the memory element.

The processing circuitry may be configured in the read mode to determine a time delay between a signal event in the input signal and a corresponding signal event in the response signal; and determine the characteristic of the memory element based on the time delay.

The processing circuitry may comprise a time-to-digital converter configured to determine the time delay and output a digital time delay signal. The processing circuitry may be configured to determine the characteristic of the memory element based on the digital time delay signal.

The characteristic may comprise a resistance of the memory element or a threshold voltage of the memory element.

The processing circuitry may comprise a comparator having a first input coupled to the intermediate node, a second input coupled to the reference voltage, and a comparator output node for outputting an output signal.

The delay circuitry may further comprise a reference memory element having a reference resistance, the reference memory element coupled between the intermediate node and the reference node.

The reference memory element may comprise a reference CTT. In the read mode, the drive circuitry may be further configured to apply a gate voltage at a gate of the reference CTT to bias the reference CTT in a linear region of operation.

According to another aspect of the disclosure, there is provided a time-domain memory system, comprising: a plurality of memory elements arranged in a memory matrix having columns and rows, each of the plurality of memory elements having a programmable resistance; a plurality of bit lines, each bit line coupled with one of a drain or source of a different column of the plurality of memory elements, wherein another of the drain and source of the plurality of memory elements is coupled to a reference voltage node, and wherein each of the plurality of bit lines is coupled to a respective bit line input node via a circuit element having a reactance; a plurality of word lines, each word line coupled with gates of a different row of the plurality of memory elements; and processing circuitry configured to monitor one or more read voltages on one or more of the plurality of bit lines.

Each circuit element may comprise a capacitor or an inductor.

One or more of the plurality of memory elements may comprise a reference memory element, wherein for each reference memory element the processing circuitry is configured to: monitor a respective read voltage; determine the programmable resistance of the reference memory element; and compare the programmable resistance to a predetermined reference resistance.

The processing circuitry may be configured to: output a flag on determining that the programmable resistance differs from the predetermined reference resistance by more than a predetermined threshold amount.

According to another aspect of the disclosure, there is provided delay circuitry, comprising: an input node for receiving a time-varying input signal; an intermediate node; a circuit element having a reactance, the circuit element coupled between the input node and the intermediate node; a memory element having a programmable resistance, the memory element coupled between the intermediate node and a reference node.

According to another aspect of the disclosure, there is provided memory circuitry comprising the delay circuitry described above, and processing circuitry coupled to the intermediate node, the processing circuitry configured to determine a characteristic of the memory element based on a time-varying response signal at the intermediate node.

According to another aspect of the disclosure, there is provided a physically unclonable function comprising the delay element described above.

According to another aspect of the disclosure, there is provided a physically unclonable function, comprising: a first configurable signal path comprising a first delay element; a second configurable signal path comprising a second delay element, wherein the first and second delay elements each comprise a delay element as described above.

According to another aspect, there is provided an electronic device comprising a delay element, a memory system, or a PUF as described above. The device may comprise one of a mobile computing device, a laptop computer, a tablet computer, a games console, a remote-control device, a home automation controller or a domestic appliance, a toy, a robot, an audio player, a video player, or a mobile telephone, and a smartphone.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 is a schematic diagram of a delay circuit;

FIG. 2 is a schematic diagram of a delay circuit;

FIG. 3 is a schematic diagram of a memory system;

FIG. 4 is a flow diagram of a read operation using the memory system of FIG. 3;

FIG. 5 is a schematic diagram of a system comprising the memory system of FIG. 3;

FIG. 6 is a schematic diagram of a physically unclonable function; and

FIG. 7 is a schematic diagram of a delay element.

### DESCRIPTION OF EMBODIMENTS

Embodiments of the present disclosure aim to address or at least ameliorate one or more of the challenges associated with conventional memory technologies.

It is proposed to provide a time-domain based memory element and a time-domain readout technique for determining the status of data stored in the memory element. The memory element may be implemented as an element having a variable resistance, such as a memristor or a charge trap transistor (CTT). In the case of a memristor, resistance can be controlled using an internal filament state of the memristor. In the case of a CTT device, resistance can be varied by programming the threshold voltage (VT) of the device. For measurement, rather than taking static measurements, as is the case for conventional non-volatile technology, a reactive circuit (e.g. using a capacitor) may be provided to introduce a step or impulse function input to the CTT. The temporal response to that step or impulse function of the CTT may be sensed and digitized to obtain a measurement of the resistance of the variable resistance element (memristor or CTT).

The proposed architecture provides fine-resolution multilevel bit storage. Temperature resilience may be improved via differential referencing. Reliability may be monitored using one or more integrated canary circuits, as will be described in more detail below.

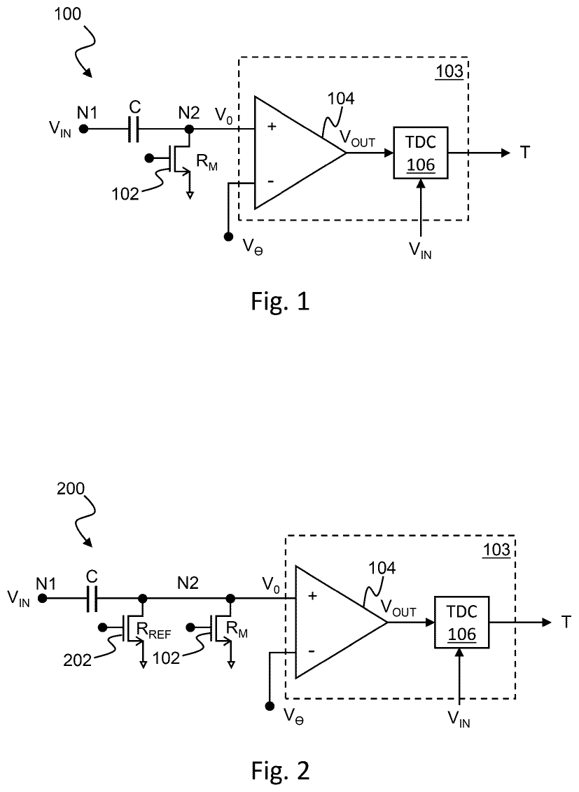

FIG. 1 is a schematic diagram of an example memory (or delay) circuit 100 comprising a memory element 102 having a programmable resistance RM, an input capacitor C, and processing circuitry 103 comprising an op-amp 104 and a time-to-digital converter (TDC) 106.

The input capacitor C is coupled between an input node N1 and a first (e.g. non-inverting) input of the op-amp 104 (intermediate node N2). The input capacitor C provides a capacitive coupling between the input node N1 and the intermediate node N2. A second (e.g. inverting) input of the op-amp 104 is couple to a known reference voltage Vθ. An output of the op-amp 104 is coupled to an input of the TDC 106.

The memory element 102 is coupled between the intermediate node N2 (i.e. the first input of the op-amp 104) and a reference voltage, in this case ground (0 V). In this example, the memory element 102 comprises a CTT. The resistance RM of the memory element 102 can be programmed by adjusting the threshold voltage VT of the CTT. This allows the memory element 102 to store data based on the level of the programmed threshold voltage VT. To operate as a resistive element the CTT is biased into its linear region of operation. To do so, the voltage between drain and source (VDS) may be set to be relatively low, for example around 100 mV. The memory element 102 may be configured to be conductive or non-conductive. For example, the CTT may be configured in an open (non-conductive) state, or a closed (conductive) state by adjusting a gate voltage VG at a gate of the CTT.

With the memory element 102 programmed with a known threshold voltage VT, when a time varying stimulus, such as a step or impulse function, is applied to the input node NI, the memory element 102 will act as a resistor having a known resistance RM. This, in turn, will lead to a time-varying voltage V0 at the intermediate node N2. The time taken for the voltage V0 at the intermediate node N2 to reach a predetermined voltage, such as the known reference voltage Ve, can be determined using the following equation:

$${V}_{0} = {V}_{in} {e}^{\frac{- tk ( {V}_{GS} - {V}_{T} )}{C}}$$

Where VIN is the input voltage at the input node N1 (i.e. the step or impulse function), t is time, VGS is the voltage between gate and source of the memory element 102, VT is the threshold voltage of the memory element 102, and C is the value of capacitance of the input capacitor C.

Thus, the op-amp 104 is configured to compare the voltage V0 at the intermediate node N2 to the reference voltage Vθ and output a time-varying output voltage VOUT. For example, after application of a step function in the input voltage VIN at the input node N1, the voltage V0 at the intermediate node N2 will increase. When the voltage V0 rises to be greater than the reference voltage Vθ, the output voltage VOUT will transition from a low state to a high state. The output voltage VOUT is then provided to the TDC 106 which generates an output time T.

With knowledge of the output time T, t is then possible to determine the threshold voltage VT of the memory element 102, and therefore the data stored in the memory element 102. For example, the threshold voltage VT of the memory element 102 may be calculated using the below equation:

$${V}_{T} = {V}_{GS} + \frac{C}{kt} ln ( \frac{{V}_{0}}{{V}_{in}} )$$

It will be understood that the memory element 102 may be programmed using any suitable programming technique. For example, the threshold voltage VT may be set using any known technique. Equally, the memory element 102 may be erased using any suitable erasure technique. Erasing may comprise resetting the threshold voltage VT of the CTT. Thus, the circuit 100 may be operated in a programming mode, in which the threshold voltage VT is programmed or set, in a reading mode in which the threshold voltage VT of the memory element 102 is determined, and an erasure mode in which the threshold voltage VT of the memory element 102 is reset or reprogrammed. Optionally, the erasure mode may be encompassed in the programming mode.

In the reading mode, a time-varying stimulus may be applied at the input node N1 of the circuit 100 to induce a delayed response at the intermediate node N2. The delay in the change in voltage V0 at the intermediate node N2 is proportional to the resistance RM (i.e. the threshold voltage VT) of the memory element 102, as explained above.

Whilst in the example in FIG. 1, the memory element 102 is implemented as a CTT, it will be understood that other programmable resistive elements may be used as the memory element 102, such as a memristor.

It will be appreciated that whilst the memory circuit 100 in FIG. 1 can be used to measure an absolute value of the resistance RM (or the threshold voltage VT) of the memory element 102, it may be preferable to determine a relative value of the resistance RM so as to account for ageing and temperature effects associated with the circuit 100. To do so, a reference memory element may optionally be provided.

FIG. 2 is a schematic diagram of an example memory circuit 200 which is a variation of the memory circuit 100 shown in FIG. 1, like parts being denoted like numerals. The memory circuit 200 differs from the memory circuit 100 of FIG. 1 by the addition of a reference memory element 202 having a reference resistance RREF.

Like the memory element 102, the reference memory element 202 may be configured to be conductive or non-conductive. For example, when implemented as a CTT, a gate voltage VG at a gate of the reference memory element 202 may be adjusted to configure the reference memory element 202 in an open (non-conductive) state and a closed (conductive) state.

Thus, when operating in the reading mode, the memory circuit 200 may be configurable in one of two states. In a first state, the reference memory element 202 may be configured in a conductive state and the memory element 102 may be configured in a non-conductive state. In this first state, a time-varying stimulus may then be applied at the input node N1 to determine a baseline measurement of an output time TREF of the TDC 106 for a known threshold voltage VT of the reference memory element 202. In a second state, the reference memory element 202 may be configured in a non-conductive state and the memory element 102 may be configured in a conductive state. In the second state, a time-varying stimulus may be applied at the input node N1 to determine an output TM relating to the threshold voltage VT of the programmed memory element 102.

The ratio of delay TREF associated with the reference memory element 202 to delay TM associated with the memory element 102 is equal to the ratio of the resistance RREF of the reference memory element 202 to the resistance RM of the memory element 102, i.e.:

$$\frac{{T}_{REF}}{{T}_{M}} = \frac{{R}_{REF}}{{R}_{M}}$$

This relationship can be used to determine the resistance RM of the memory element 102 and hence infer the threshold voltage VT of the memory element 102. Since ageing and temperature are likely to affect the memory element 102 and reference memory element 202 equally, by using the above relationship a determination of the resistance RM of the memory element 102 can be obtained which is less sensitive to ageing and temperature effects. The threshold voltage VT of the memory element 102 can then be determined based on this resistance RM.

Thus, the circuit 100 provides a novel architecture for reading programmable resistive memory elements which may be implemented as part of a memory solution, such as a random-access memory (RAM) solution.

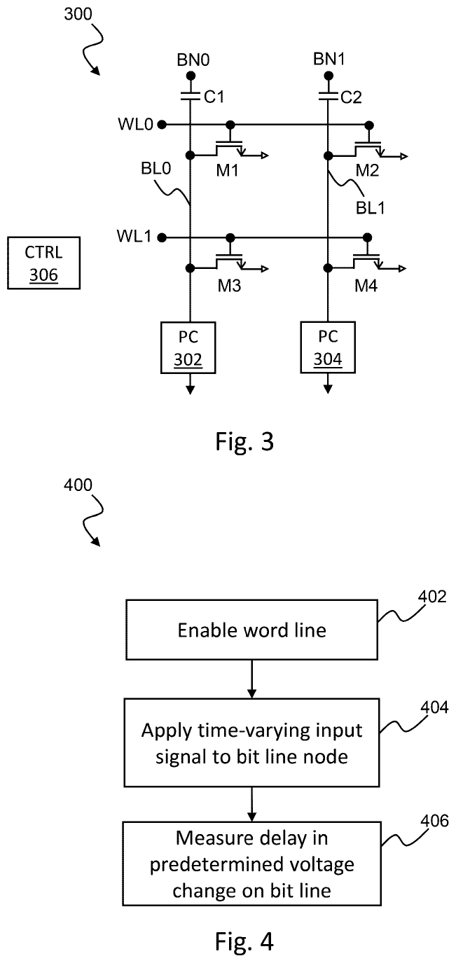

FIG. 3 is a schematic diagram illustrating a memory system 300 according to embodiments of the present disclosure. The memory system 300 comprises first, second, third and fourth memory elements M1, M2, M3, M4. The memory system 300 further comprises first and second processing circuits 302, 304, and control circuitry 306. Each of the memory elements M1:M4 are CTTs in this example. Specifically, the memory elements M1:M4 are NMOS CTT devices. In other embodiments, however, the memory elements M1:M4 may be implemented as PMOS devices or using other programmable resistive elements, such as memristors. The first and second processing circuit 302, 304 may each comprise the processing circuitry 103 shown in FIGS. 1 and 2. In a variation of the arrangement shown in FIG. 3, a multiplexer may be provided with a single instance of the processing circuitry 103 of FIGS. 1 and 2.

The memory elements M1:M4 are arranged in a two-by-two matrix (or crossbar configuration) consisting of first and second bit lines BL0, BL1 and first and second word lines WL0, WL1. It will be appreciated that the system 300 may be expanded to any size matrix with additional memory elements M1:M4.

Gates of the first and second memory elements M1, M2 are coupled to the first bit line WL0. Gates of the third and fourth memory elements M3, M4 are coupled to the second word line WL1. Drains of the first and third memory elements M1, M3 are coupled to the first bit line BL0. Drains of the second and fourth memory elements M2, M4 are coupled to the second bit line BL1. A first input capacitor C1 is provided between the first bit line BL0 and a first bit line node BN1. A second input capacitor C2 is provided between the second bit line BL1 and a second bit line node BN2. The first and second bit lines BL0, BL1 are also coupled to respective first and second processing circuits 302, 304. Sources of the first, second, third, and fourth memory elements M1:M4 are coupled to a reference voltage, in this case ground.

Thus, each of the memory elements M1:M4 are arranged in a similar manner to that shown in FIG. 1. However, the matrix arrangement allows each of the memory elements M1:M4 to be individually interrogated to ascertain their corresponding characteristic (e.g. resistance or threshold voltage).

The control circuitry 306 may control application of signals to the first and second bit line nodes BN0, BN1 and the first and second word lines WL0, WL1. The control circuitry 306 may also be in communication with processing circuits 302, 304, for example to provide the processing circuits 302, 304 with an indication of signals applied to the bit and word lines BL0, BL1, WL0, WL1. It will be appreciated that the control circuitry 306 and the first and second processing circuits 302, 304 may be implemented as a single control and processing unit.

Operation of the system 300 for reading characteristics (e.g. resistance or threshold voltage) of the various memory elements M1:M4 will now be described with reference to FIG. 4. It will be appreciated that each of the memory elements M1:M4 may be programmed in a manner known in the art. Such programming operations will not be described in more detail here. It will also be appreciated that reset operations may be similar to programming operations and will also therefore not be described in more detail here.

FIG. 4 is a flow diagram illustrating an example process 400 for reading one of the memory elements M1, M4. Whilst the process 400 will be described specifically for reading the first memory element M1, it will be appreciated that such a process 400 may be used to read any of the memory elements M1:M4.

At step 402, the first and second memory elements M1, M2 are placed in a read mode. To do so, the first word line WL0 is biased so as to enable current to flow through respective first and second memory elements M1, M2 between their respective drain and source. For example, the first word line WL0 may be controlled to bias the first and second memory elements M1, M2 in their linear region of operation. The third and fourth memory elements M3, M4 may be maintained in a standby mode in which the second word line WL1 is biased such that no current flows between drain and source of respective third and fourth memory elements M3, M4.

At step 404, a time-varying input signal (e.g. a step function, and impulse function, a chirp, or a sweep) is applied to the first bit line node BN0.

At step 406, the first processing circuit 302 may be configured to monitor the first bit line BL0 to determine a delay in transition of a voltage on the first bit line BL0 to a known threshold voltage. The first processing circuit 302 (or the control circuitry 306) may then be configured to output the delay or an estimate of a characteristic of the first memory element M1 based on the determined delay.

The process 400 may be repeated for measurement of characteristics of any one of the memory elements M1:M4 by enabling a respective word line and injecting a time-varying input stimulus to induce a response from a respective memory element M1:M4.

Whilst memory elements such as CTTs can be used in RAM architectures such as that shown in FIG. 3, CTT memory state can fail for various reasons. As is known in the art, CTTs store information by holding electrons (or holes) in an insulting layer that has defect sites (“traps”). There are several mechanisms that can cause charge to move, leak or tunnel out of those defect sites leading to memory state failure. For example, charge can tunnel through thin oxide layers, particularly at high temperatures. For example, charge can migrate between trap sites, leading to partial loss or redistribution of stored charge. After months or years, the threshold difference between different programmed states shrinks, which eventually cause a CTT bit to be read as a different value to that which was originally programmed.

To address or at least ameliorate issues associated with CTT state instability, one or more reference or canary circuits, such as the memory circuit 100 shown in FIG. 1, may be provided in addition to a CTT-based memory system. Such a canary circuit may be provided to determine if the CTT-based memory system has been exposed to adverse (deleterious) conditions. Such a canary circuit may also be used to determine when to refresh data stored in an associated CTT-based memory system.

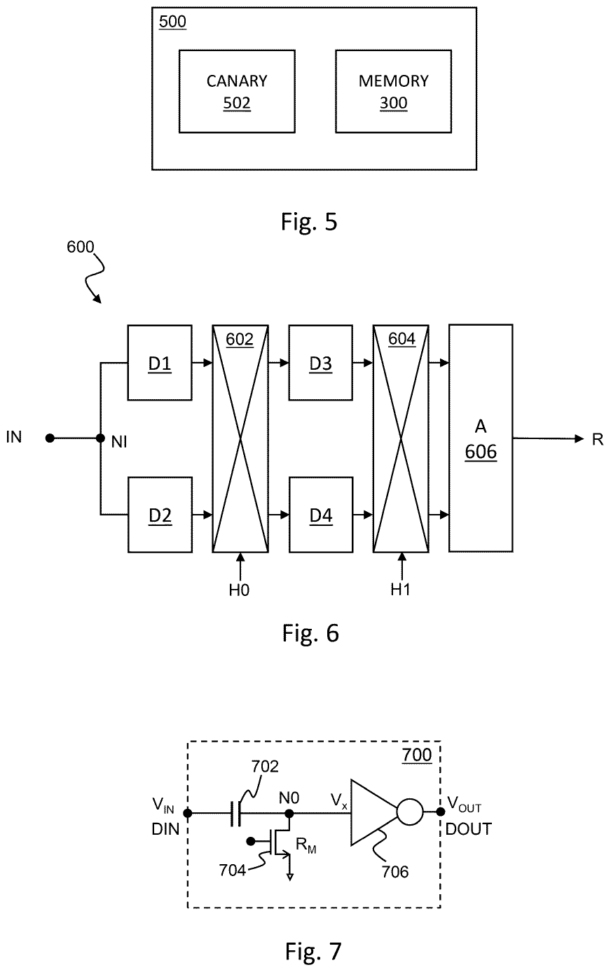

FIG. 5 is a schematic diagram of an example system 500 comprising the memory system 300 of FIG. 3 and a canary circuit 502. The canary circuit 502 may comprise the circuit 100 or circuit 200 of FIG. 1 or 2. The memory element 102 of the canary circuit 502 may have a greater sensitivity to ageing or environmental effects than memory elements of an associated CTT-based memory system. In any case, the canary circuit 502 may be configured to mimic degradation of the memory system 300 over time. The canary circuit 502 can thus be interrogated to determine a condition of the memory system 300 and/or whether refresh of the states of the memory elements M1:M4 in the memory system 300 is necessary. In response to a determination of such degradation, the memory system 300 may be reprogrammed in a manner known in the art.

The canary circuit 502 may implement a single instance of one or the circuits 100, 200. Alternatively, the canary circuit 502 may implement multiple instances of one or both circuits 100, 200 in parallel. Each instance may be programmed with a different threshold voltage VT level. Each programmed threshold voltage level may be associated with a state of the memory elements M1:M4. For example, if each of the memory elements M1:M4 can be programmed with one of four states (or VT levels), the canary circuit 502 may comprise four instances of the circuit 100, each programmed to one of the four states. In doing so, the canary circuit 502 may provide a more accurate indication of conditions of the memory system 300.

Whilst in the above circuits 100, 200 and systems 300, 500 a capacitor is used to introduce a time response to the respective memory circuits, it will be understood that a capacitor may be replaced by any suitable reactive element or combination of reactive elements. An example of such a reactive element is an inductor. If an inductor is implemented in place of or in addition to one or more capacitors, the time response may now comprise a low-pass response with an associated time constant of L/R, where L is the inductance of the inductor.

The memory or delay circuits 100, 200 are described above for use in a memory system 300. It will be appreciated that such circuits 100, 200 have additional applications.

For example, either of the memory circuits 100, 200 may be implemented as part of a physically unclonable function (PUF). As is known in the art, a PUF is a hardware security primitive that provides a way to use natural, random manufacturing variations in silicon (or other semiconductor substrate) to create a secure, unclonable fingerprint for an integrated circuit.

FIG. 6 is a schematic diagram of a delay-based PUF 600. The PUF 600 is described in detail in “RC PUF: A Low-Cost and an Easy-to-Design PUF for Resource-Constrained IoT Devices” (Lee, S.; Oh, M; Kang, Y; Choi, D).”, the content of which is hereby incorporated by reference in its entirety.

The PUF 600 comprises first, second, third, and fourth delay elements D1, D2, D3, D4 and first and second routers 602, 604.

An input of each of the first and second delay elements D1, D2 are coupled to an input node NI. Outputs of each of the first and second delay elements D1, D2 are coupled to first and second inputs the first router 602. A first output of the first router 602 is coupled to an input of the third delay element D3. A second output of the first router 602 is coupled to an input of the fourth delay elements D4. Outputs of each of the third and fourth delay elements D3, D4 are coupled to first and second inputs of the second router 604. First and second outputs of the second router 604 are coupled to an arbiter 606. The arbiter 606 may comprise a latch or a D-type circuit.

The first router 602 is configured to selectively route the output of the first delay element D1 to the input of one of the third and fourth delay elements D3, D4 and selectively route the output of the second delay element D2 to the input of the other of the third and fourth delay elements D3, D4 based on a first challenge bit H0.

The second router 604 is configured to selectively route the output of the third delay element D3 to one of the first and second inputs of the arbiter 606 and selectively route the output of the fourth delay element D4 to the other of the first and second inputs of the arbiter 606 based on a second challenge bit H1.

To challenge the PUF 600, the challenge bits H0, H1 are set, and a step function is applied at the input node N0. The step function travels through the PUF 600 via the various delay elements D1:D4 and routers 602, 604 before reaching the arbiter 606. Depending on the route taken, the step function will reach the arbiters first and second inputs at different times. Thus, the arbiter 606 records which path is faster and outputs a response R. The response R may then be compared with the challenge to determine whether the PUF 600 is valid.

It is proposed to implement the PUF 600 with one or more of the delay elements D1:D4 implemented with an RC circuit comprising a programmable resistive element, such as a CTT or other silicon-oxide-nitride-oxide-silicon (SONOS) device, or a memristor. The programmable resistive element (memory element) may store the information or secret. Delays of the delay elements D1:D4 may be trimmed to be the same over multiple parts by programming the resistive elements in each of the delay elements D1:D4.

FIG. 7 is a schematic diagram of a delay circuit 700 which may be implemented as any one of the delay elements D1:D4 of the PUF 600.

The delay circuit 700 comprises an input capacitor 702, a programmable resistive element 704, and an inverter 706.

The input capacitor 702 may be replaced with any other reactive element, such as an inductor, or any combination of reactive elements. The input capacitor is coupled between a delay input node DIN and an intermediate node N0.

The programmable resistive element 704 may be implemented as a CTT or other SONOS device, or a memristor. The programmable resistive element 704 is coupled between the intermediate node N0 and a reference voltage node (e.g. a ground reference).

An input of the inverter 706 is coupled to the intermediate node N0. An output of the inverter 706 is coupled to a delay output node DOUT. The inverter 706 may be provided to buffer successive stages in the PUF 600 to avoid loading.

The delay circuit 700 is configured to apply a delay to a signal received at the delay input node DIN proportional to the RC constant associated with the combination of the capacitor 702 and the programmable resistive element 704. The delay tn may be defined as follows:

tₙ=ln(2)·RₙCₙ

Providing a CTT as the programmable resistive element 704 produces a high-pass filter with an output inverter. After a step in input voltage VIN is applied at the delay input node DIN, the voltage Vx at the intermediate node N0 will decay. When the voltage Vx is half of the peak of the step in input voltage VIN applied at the delay input node DIN, the inverter 706 will toggle high to generate an output voltage VOUT.

From the above, the drain current ID of the resistive element 704 implemented as a field effect transistor (FET) can be defined as follows:

$${I}_{D} = \frac{W}{L} μ {C}_{ox} \{ ( {V}_{GS} - {V}_{T} ) {V}_{DS} - \frac{{V}_{DS}^{2}}{2} \}$$

Where μ is the carrier mobility of the FET, Cₒₓ is the oxide capacitance per unit area of the semiconductor structure, VGS is the gate source voltage, VT is the threshold voltage, VDS is the drain source voltage.

When VDS<<VGS−VT, the above can be simplified as follows:

$${R}_{MOS} = \frac{{V}_{DS}}{{I}_{DS}} = \frac{1}{k ( {V}_{GS} - {V}_{T} )}$$

$$where k = \frac{W}{L} μ {C}_{ox}$$

Thus, the delay tn is given by:

$${t}_{n} = ln ( 2 ) \frac{{C}_{n}}{k ( {V}_{GS} - {V}_{T} )}$$

Thus, to configure the delay tn of the delay element, the capacitance Cn of the capacitor 702 and the resistance Rn of the programmable resistive element 704 can be set. In the PUF 600, it is desirable that the delay of each delay element D1:D4 is different. The capacitance Cn can be used to crudely set the delay tn, and then the resistive element 704 can be used to tune the delay tn.

In all of the above embodiments, the various capacitors are shown as distinct circuit elements. It will be appreciated however that the capacitors may be provided by parasitic capacitance.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Memory circuitry, comprising:
an input node for receiving a time-varying input signal;
an intermediate node;
a circuit element having a reactance, the circuit element coupled between the input node and the intermediate node;
a memory element having a programmable resistance, the memory element coupled between the intermediate node and a reference node, and processing circuitry coupled to the intermediate node, the processing circuitry configured to determine a characteristic of the memory element based on a time-varying response signal at the intermediate node.

2. The memory circuitry of claim 1, wherein the memory element comprises a charge trap transistor having a programmable threshold voltage.

3. The memory circuitry of claim 1, wherein the memory element comprises a memristor.

4. The memory circuitry of claim 1, wherein the circuit element comprises a capacitor or an inductor.

5. The memory circuitry of claim 1, wherein the time-varying input signal comprises a step function, an impulse function, a chirp, or a sweep.

6. The memory circuitry of claim 1, further comprising:
drive circuitry coupled to the input node, the drive circuitry configured in a read mode to apply the time-varying input signal at the input node.

7. The memory circuitry of claim 6, wherein the memory element comprises a charge trap transistor (CTT), wherein in the read mode the drive circuitry is further configured to apply a gate voltage at a gate of the CTT to bias the CTT in a linear region of operation.

8. The memory circuitry of claim 6, wherein, in a programming mode, the drive circuitry is configured to program the programmable resistance of the memory element.

9. The delay circuitry of claim 8, wherein the drive circuitry is configured to program the programmable resistance of the memory element by applying a programming voltage at a gate of the memory element.

10. The memory circuitry of claim 1, wherein the processing circuitry is configured in the read mode to:
determine a time delay between a signal event in the input signal and a corresponding signal event in the response signal; and
determine the characteristic of the memory element based on the time delay.

11. The memory circuitry of claim 8, wherein the processing circuitry comprises:
a time-to-digital converter configured to determine the time delay and output a digital time delay signal, the processing circuitry configured to determine the characteristic of the memory element based on the digital time delay signal.

12. The memory circuitry of claim 1, wherein the characteristic comprises a resistance of the memory element or a threshold voltage of the memory element.

13. The memory circuitry of claim 1, wherein the processing circuitry comprises:
a comparator having a first input coupled to the intermediate node, a second input coupled to the reference voltage, and a comparator output node for outputting an output signal.

14. The delay circuitry of claim 1, further comprising:
a reference memory element having a reference resistance, the reference memory element coupled between the intermediate node and the reference node.

15. The delay circuitry of claim 14, wherein the reference memory element comprises a reference CTT, wherein in the read mode, the drive circuitry is further configured to apply a gate voltage at a gate of the reference CTT to bias the reference CTT in a linear region of operation.

16. A time-domain memory system, comprising:
a plurality of memory elements arranged in a memory matrix having columns and rows, each of the plurality of memory elements having a programmable resistance;
a plurality of bit lines, each bit line coupled with one of a drain or source of a different column of the plurality of memory elements, wherein another of the drain and source of the plurality of memory elements is coupled to a reference voltage node, and wherein each of the plurality of bit lines is coupled to a respective bit line input node via a circuit element having a reactance;
a plurality of word lines, each word line coupled with gates of a different row of the plurality of memory elements; and
processing circuitry configured to monitor one or more read voltages on one or more of the plurality of bit lines.

17. The time-domain memory system of claim 16, wherein each circuit element comprises a capacitor or an inductor.

18. The time-domain memory system of claim 16, wherein one or more of the plurality of memory elements comprises a reference memory element, wherein for each reference memory element the processing circuitry is configured to:
monitor a respective read voltage;
determine the programmable resistance of the reference memory element; and
compare the programmable resistance to a predetermined reference resistance.

19. The time-domain memory system of claim 18, wherein the processing circuitry is configured to:
output a flag on determining that the programmable resistance differs from the predetermined reference resistance by more than a predetermined threshold amount.

20. An electronic device comprising the memory circuitry of claim 1, wherein the device comprises one of a mobile computing device, a laptop computer, a tablet computer, a games console, a remote-control device, a home automation controller or a domestic appliance, a toy, a robot, an audio player, a video player, or a mobile telephone, and a smartphone.

21. (canceled)
